(19) United States
(12) Patent Application Publication
(10) Pub. No.: US 2015/0108584 A1
(43) Pub. Date: Apr. 23, 2015

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Yangsoo Son, Gyeonggi-do (KR); Hyerim Moon, Seoul (KR); Hagju Cho, Gyeonggi-do (KR); Jeongnam Han, Seoul (KR); Joon Goo Hong, Gyeonggi-do (KR)

(21) Appl. No.: 14/582,429

(22) Filed: Dec. 24, 2014

Related U.S. Application Data
(62) Division of application No. 13/690,456, filed on Nov. 30, 2012.

(30) Foreign Application Priority Data
Dec. 9, 2011 (KR) 10-2011-0131994

(51) Int. Cl. H01L 27/11; H01L 29/51; H01L 29/78

(52) U.S. Cl. CPC H01L 27/1104; H01L 29/7848; H01L 29/517
USPC 257/401

(57) ABSTRACT

A semiconductor device includes a first device isolation pattern defining a first active region, a second device isolation pattern defining a second active region, a first gate disposed on the first active region, the first gate including a gate insulating pattern of a first thickness and a second gate disposed on the second active region, the second gate including a gate insulating pattern of a second thickness greater than the first thickness. A top surface of the first device isolation pattern is curved down toward the first active region such that the first active region has an upper portion protruded from the top surface and rounded corners.

### CROSS-REFERENCE TO RELATED APPLICATIONS

This application is a divisional of U.S. application Ser. No. 13/690,456 filed on Nov. 30, 2012, which is claims priority under 35 U.S.C. §119 to Korean Patent Application No. 10-2011-0131994, filed on Dec. 9, 2011, in the Korean Intellectual Property Office, the disclosure of which is incorporated by reference herein in its entirety.

### TECHNICAL FIELD

Embodiments of the inventive concepts relate to a semiconductor device and a method of fabricating the same, and more particular, to a transistor of a Static Random Access Memory (SRAM) and a method of fabricating the same.

### DISCUSSION OF RELATED ART

Semiconductor devices are widely used in various industrial areas such as electronic systems, automobiles and/or vessels because of small size, multi-function and/or low fabrication cost thereof. The semiconductor devices can be categorized into memory devices and logic devices and consist of various electric components (such as, memory cells for storing binary data, logic circuits for processing logical operation, and/or driver circuits).

The components of the semiconductor device may operate with various voltages. For example, the semiconductor device may be configured to include a component applied with a high voltage as well as other component applied with a lower voltage.

### SUMMARY

In an embodiment, a method of fabricating semiconductor device comprises forming a first device isolation pattern in a substrate to define a first active region, forming a second device isolation pattern in the substrate to define a second active region, forming a first gate insulating pattern on the first active region and the second active region, overetching the first gate insulating pattern of the first active region such that the first device isolation pattern has a top surface curved down toward the first active region and the first active region has an upper portion protruded from the top surface and rounded corners, forming a second gate insulating layer on the upper portion of the first active region and the first gate insulating pattern of the second active region, and forming a conductive layer on the second gate insulating pattern.

In an embodiment, the method further comprises forming sacrificial patterns on the first gate insulating pattern of the first and second active regions. The method further comprises forming an interlayer insulation pattern between the sacrificial patterns and removing the sacrificial patterns prior to the step of overetching the first gate insulating pattern of the first active region.

In an embodiment, overetching the first gate insulating pattern comprises forming a mask on the second region to cover the first gate insulating pattern of the second active region, removing the first gate insulating pattern of the first region, and removing the mask.

In an embodiment, the gate first insulating pattern is formed of a material having a first dielectric constant, and the second gate insulating pattern is formed of a material having a second dielectric constant greater than that of the first insulating pattern.

In an embodiment, the gate insulating pattern includes a layer of silicon oxide, and the gate insulating layer includes a layer of metal oxide.

In an embodiment, the method further comprises removing the conductive layer and the second gate insulating layer to the level of a top surface of the interlayer insulating pattern so that a first gate is formed on the first active region, and a second gate is formed on the second active region. The first gate includes a second gate insulating pattern and a first gate electrode. The second gate includes the first gate insulating pattern, a second gate insulating pattern, and a second gate electrode. The second gate electrode of the second gate has a U-shaped structure. The rounded corners increase an effective channel width of the first gate.

In an embodiment, the gate insulating pattern of the second gate includes a silicon oxide layer disposed on the second active region and a metal oxide layer disposed on the silicon oxide layer. The gate insulating pattern of the first gate is the metal oxide layer.

In an embodiment, a semiconductor device comprises a first device isolation pattern defining a first active region, a second device isolation pattern defining a second active region, a first gate disposed on the first active region, the first gate including a gate insulating pattern of a first thickness and a second gate disposed on the second active region, the second gate including a gate insulating pattern of a second thickness greater than the first thickness. A top surface of the first device isolation pattern is curved down toward the first active region such that the first active region has an upper portion protruded from the top surface and rounded corners.

In an embodiment, a first voltage level is applied to the first gate, and a second voltage level is applied to the second gate. The second voltage level is higher than the first voltage level.

In an embodiment, the second gate is PMOS transistor and includes patterns in source/drain regions. The patterns have compressive residual stress.

In an embodiment, a semiconductor device comprises a static random access memory cell (SRAM cell) transistor including a gate insulating pattern of a first thickness and an active region having rounded corners and a transistor including a gate insulating pattern of a second thickness greater than the first thickness. The rounded corners increase an effective width of the static memory cell transistor. The transistor includes a gate insulating pattern of a second thickness greater than the first thickness. A first voltage level is applied to the static memory cell transistor and a second voltage level higher than the first voltage level is applied to the transistor.

In an embodiment, the gate insulating pattern of the transistor includes a silicon oxide layer disposed on the second active region and a metal oxide layer disposed on the silicon oxide layer. The gate insulating pattern of the SRAM cell transistor is the metal oxide layer. The transistor is a PMOS transistor including source/drain regions, the source/drain regions including patterns having compressive residual stress.

### BRIEF DESCRIPTION OF THE DRAWINGS

Example embodiments will be more clearly understood from the following brief description taken in conjunction with the accompanying drawings. The accompanying drawings represent non-limiting, exemplary embodiments as described herein.

FIG. 1 is a sectional view of a semiconductor device according to exemplary embodiments of the inventive concept.

FIGS. 2 through 9 are sectional views illustrating a method of fabricating a semiconductor device according to exemplary embodiments of the inventive concept.

FIG. 10 is an equivalent circuit diagram of a semiconductor device according to exemplary embodiments of the inventive concept.

FIG. 11A is a plan view of a semiconductor device according to exemplary embodiments of the inventive concept.

FIG. 11B is a sectional view taken along line I-I′ of the semiconductor device of FIG. 11A.

FIG. 11C is a sectional view taken along a line II-II′ of the semiconductor device of FIG. 11A.

FIGS. 12A through 17A are plan views illustrating a method of fabricating a semiconductor device according to exemplary embodiments of the inventive concept.

FIGS. 12B through 17B are sectional views taken along lines I-I′ of FIGS. 12A through 8A, respectively.

FIGS. 12C through 17C are sectional views taken along lines II-II′ of FIGS. 12A through 8A, respectively.

FIGS. 18A and 19A are plan views illustrating a method of fabricating a semiconductor device according to other embodiment of the inventive concept.

FIGS. 18B and 19B are sectional views taken along lines I-I′ of FIGS. 18A and 19A, respectively.

FIGS. 18C and 19C are sectional views taken along lines II-II′ of FIGS. 18A and 19A, respectively.

FIG. 20 is a block diagram illustrating a memory card including a semiconductor device, in which at least one of the SRAM cells according to example embodiment of the inventive concept is provided.

It should be noted that these figures are intended to illustrate the general characteristics of methods, structure and/or materials utilized in certain exemplary embodiments and to supplement the written description provided below. These drawings are not, however, to scale and may not precisely reflect the precise structural or performance characteristics of any given embodiment, and should not be interpreted as defining or limiting the range of values or properties encompassed by exemplary embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Exemplary embodiments of the inventive concepts will now be described more fully with reference to the accompanying drawings, in which exemplary embodiments are shown. Exemplary embodiments of the inventive concepts may, however, be embodied in many different forms and should not be construed as being limited to the embodiments set forth herein; rather, these embodiments are provided so that this disclosure will be thorough and complete, and will fully convey the concept of exemplary embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments of the inventive concepts are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

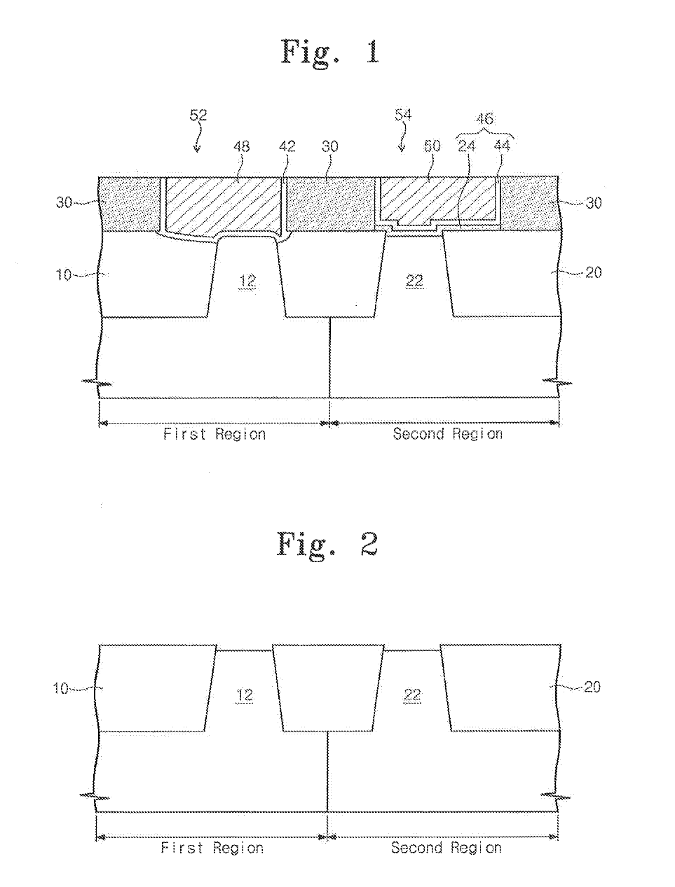

FIG. 1 is a sectional view illustrating a semiconductor device according to exemplary embodiments of the inventive concept.

Referring to FIG. 1, a semiconductor device may include a substrate 11 including active regions 12 and 22 defined by device isolation patterns 10 and 20 and a plurality of gates 52 and 54 provided on the substrate 11. In addition, the semiconductor device may further include interlayer insulating patterns 30 electrically isolating the gates 52 and 54 from each other.

The substrate 11 may be a semiconductor substrate (for example, including silicon, germanium or silicon/germanium). The substrate 11 may include a first region for a low voltage transistor applied with a low voltage and a second region for a high voltage transistor applied with a high voltage. For example, transistors for memory cells and/or logic devices may be applied with the low voltage, so such transistors may be provided in the first region. Transistors for I/O devices, interfacing devices and/or logic devices may be applied with the high voltage so they may be provided in the second region.

The device isolation patterns 10 and 20 may be formed in the substrate 11. A first device isolation pattern 10 is formed in the first region and a second device isolation pattern 20 is formed in the second region. The first device isolation pattern 10 and the second device isolation pattern 20 may be connected to each other.

A first active region 12 may be defined in the first region by the first device isolation pattern 10, and a second active region 22 may be defined in the second region by the second device isolation pattern 20.

In exemplary embodiments, at least a portion of the first device isolation pattern 10 may have the top surface curved down toward the first active region 12 such that the upper portion of the first active region 12 may be protruded from its adjacent first device isolation pattern 10.

The gates 52 and 54 may include a first gate 52 disposed in the first region and a second gate 54 disposed in the second region.

The first gate 52 may include a gate insulating pattern 42 and a gate electrode 48. The gate insulating pattern 42 is disposed on the upper portion of the first active region 12. The gate electrode 48 is disposed on the gate insulating pattern 42. The first gate 52 also includes its source/drain regions (not shown) provided in the first active region 12 exposed at either side of the gate electrode 48. The gate insulating pattern 42 of the first gate 52 may also be disposed on the side surface of the interlayer insulating pattern 30 adjacent thereto. In addition, the gate insulating pattern 42 of the first gate 52 may include a high-k dielectric material having a dielectric constant higher than silicon oxide. For example, the gate insulating pattern 42 of the first gate 52 may include metal oxide such as one of hafnium oxide and aluminum oxide. The gate electrode 48 of the first gate 52 may include metals or metal compounds. For example, the gate electrode 48 of the first gate 52 may include at least one of aluminum, titanium, titanium aluminum, or tantalum nitride. In addition, the gate electrode 48 of the first gate 52 may be provided to have a structure, in which the enumerated materials are stacked on one another.

In exemplary embodiments, at least a portion of a top surface of the first device isolation pattern 10 may be disposed lower than that of the first active region 12, resulting in the upper side surface of the first active region 12 being protruded from its adjacent first device isolation pattern 10. This protruded structure of the first active region 12 may increase the effective length of a channel region defined by the first gate 52. As a result, transistors including the first gate 52 may have improved reliabilities due to the reduced short channel effect.

The second gate 54 may include a gate insulating pattern 46 and a gate electrode 50. The gate insulating pattern 46 includes a silicon oxide layer 24 and a metal oxide 44. The gate insulation pattern 46 is disposed on the second active region 22. The gate electrode 50 is disposed on the gate insulating pattern 46, and source/drain regions (not shown) are provided in the second active region 22 exposed at either side of the gate electrode 50.

The gate insulating pattern 46 of the second gate 54 may be thicker than the gate insulating pattern 42 of the first gate 52. According to an embodiment of the inventive concept, the gate insulating pattern 46 of the second gate 54 may be a multi-layered structure. For example, the gate insulating pattern 46 of the second gate 54 may include a silicon oxide layer 24 and a metal oxide 44 stacked thereon. The silicon oxide layer 24 may be disposed on both the second active region 22 and the second device isolation pattern 20. The metal oxide 44 may be disposed on both the silicon oxide layer 24 and the side surface of the interlayer insulating pattern 30 adjacent thereto. For example, the metal oxide 44 of the second gate 54 may be formed of substantially the same material as the gate insulating pattern 42 of the first gate 52.

The gate electrode 50 of the second gate 54 may include metal. For example, the gate electrode 50 of the second gate 54 may be formed of substantially the same material as the gate electrode 48 of the first gate 52.

For a semiconductor device requiring two voltages such as a high voltage and a low voltage, those different voltages may be accommodated by implementing the first gate 52 and the second gate 54 to have different thicknesses.

FIGS. 2 through 9 are sectional views illustrating a method of fabricating a semiconductor device according to an embodiment of the inventive concept.

Referring to FIG. 2, device isolation patterns may be formed in the substrate 11 including the first and second regions. In the first region low voltage transistors are formed, and in the second region high voltage transistors are formed. For simplicity of explanation, description will be focused on the boundary region of the first region and the second region.

The device isolation patterns may include the first device isolation pattern 10 provided in the first region and the second device isolation pattern 20 provided in the second region. The first and second device isolation patterns 10 and 20 may be connected to each other.

The first active region 12 of the first region may be defined by the first device isolation pattern 10. The second active region 22 of the second region may be defined by the second device isolation pattern 20.

Referring to FIG. 3, preliminary insulating patterns 14 and 24 and sacrificial patterns 16 and 26 may be formed on the substrate 11. The sacrificial pattern 16 is disposed on the preliminary insulating pattern 14. The sacrificial pattern 26 is disposed on the preliminary insulating pattern 24.

The formation of the preliminary insulating patterns 14 and 24 and the sacrificial patterns 16 and 26 will be described below. A first gate insulating layer (not shown) may be formed on the resulting structure of FIG. 2. The first gate insulating layer may include a material having a first dielectric constant. The first gate insulating layer may include silicon oxide. A sacrificial layer (not shown) may be formed on the first gate insulating layer. The sacrificial layer may include a material having etch selectivity with respect to the first gate insulating layer. For example, the sacrificial layer may include polysilicon. The sacrificial layer and the first gate insulating layer may be etched to form the sacrificial patterns 16 and 26 and the preliminary insulating patterns 14 and 24. Accordingly, the first preliminary insulating pattern 14 is formed in the first region and the second preliminary insulating pattern 24 is formed in the second region. The first sacrificial pattern 16 is provided in the first region and the second sacrificial pattern 26 is provided in the second region.

During the etching process, openings may be formed between the stacked structures including the preliminary insulating patterns 14 and 24 and the sacrificial patterns 16 and 26. The openings may include a first opening 18 provided in the first region and a second opening 28 provided in the second region.

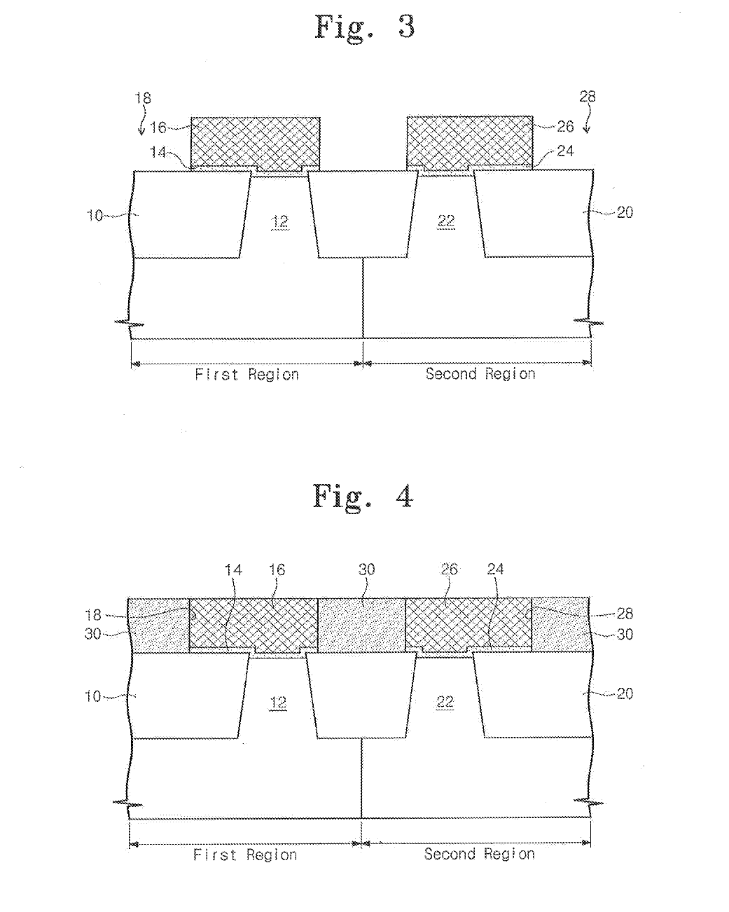

Referring to FIG. 4, interlayer insulating patterns 30 may be formed to fill the first and second openings 18 and 28.

For example, an interlayered insulating layer (not shown) may be formed on the resulting structure of FIG. 3 to a thickness enough to fill the openings 18 and 28. The interlayered insulating layer may include a material having etch selectivity with respect to the sacrificial patterns 16 and 26. Thereafter, the interlayered insulating layer is etched to expose top surfaces of the sacrificial patterns 16 and 26, and as the result of the etching, the interlayer insulating patterns 30 is formed to fill the first and second openings 18 and 28.

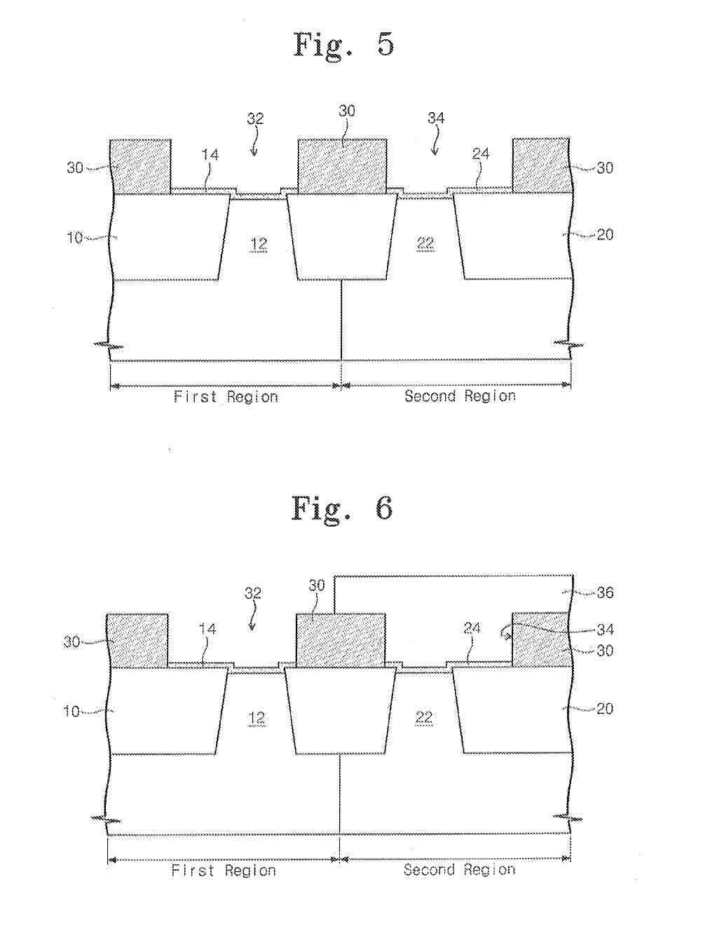

Referring to FIG. 5, the sacrificial patterns 16 and 26 may be removed to form a third opening 32 exposing the first preliminary insulating pattern 14 and a fourth opening 34 exposing the second preliminary insulating pattern 24.

Although not shown, upper portions of the preliminary insulating patterns 14 and 24 may be damaged during the removal of the sacrificial patterns 16 and 26. In exemplary embodiments, the damaged portions of the preliminary insulating patterns 14 and 24 may be removed. For example, a thermal oxidation process or a chemical vapor deposition process may apply as a post-etch treatment to cure the damaged portion.

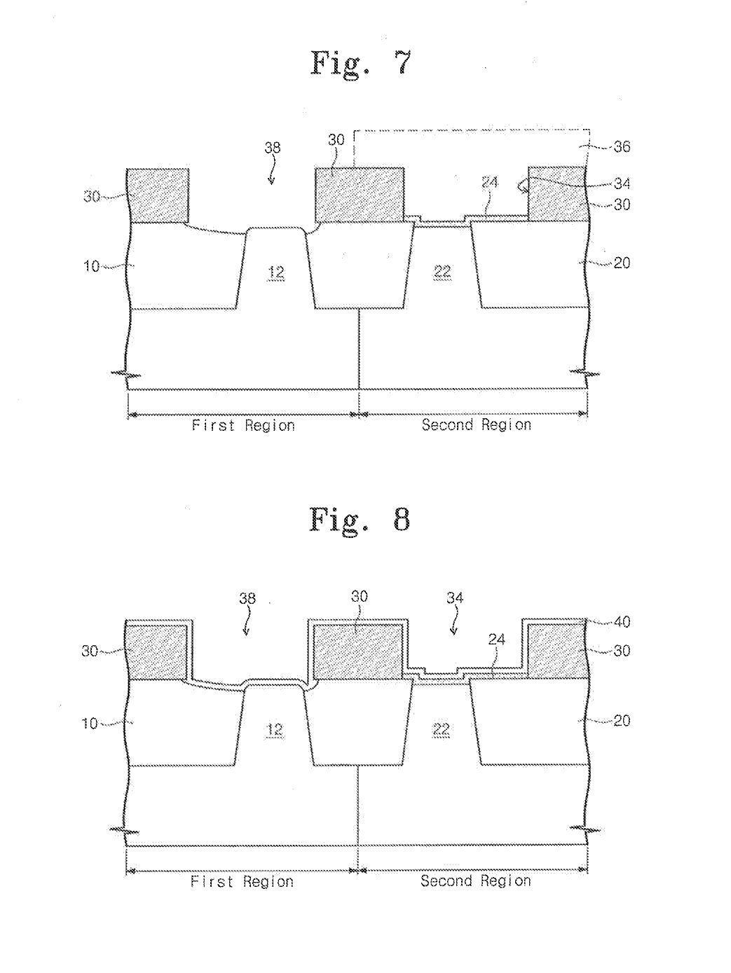

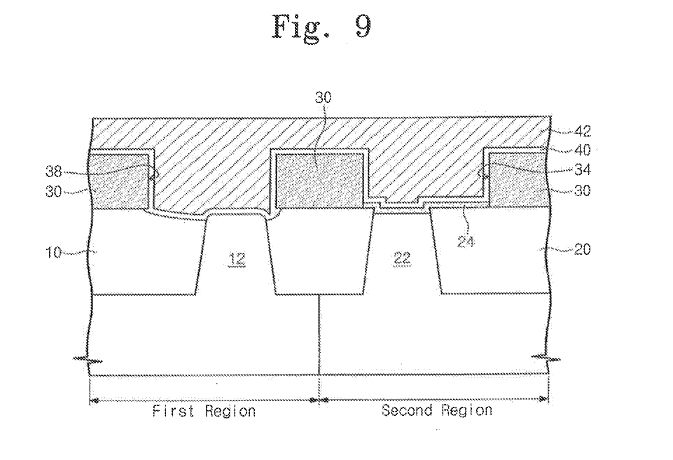

Referring to FIG. 6, a mask 36 may be formed on the second preliminary insulating pattern to fill the fourth opening 34. The mask 36 may include a photoresist layer.

Referring to FIG. 7, the first preliminary insulating pattern 14 may be overetched resulting informing a fifth opening 38 exposing the first active region 12 of the first region.

In exemplary embodiments, the first preliminary insulating patter 14 is overetched such that the top surfaces of the first device isolation pattern 10 and the first active region 12 are further etched down. Due to their different etching rates, the top surface of the first device isolation pattern 10 is etched down further than that of the first active region 12. Accordingly, the upper portion of the first active region 12 may be protruded from its adjacent first device isolation pattern 10.

The mask 36 may be removed after the removal of the first preliminary insulating pattern 14. For example, the mask 36 may be removed from the second region, thereby exposing the second preliminary insulating pattern 24. The fourth opening 34 may be formed in the second region to expose the second preliminary insulating pattern 24.

In other embodiments, the first preliminary insulating pattern 14 may be removed during the removal of the mask 36.

Referring to FIG. 8, a second insulating layer 40 may be formed conformally on the resulting structure of FIG. 7. In other words, the second insulating layer 40 covers conformally the second preliminary insulating pattern 24, the interlayer insulating patterns 30, and the first region of the substrate 11. In exemplary embodiments, the fourth opening 34 and the fifth opening 38 may not be entirely filled with the second insulating layer 40.

The second insulating layer 40 may include a material having a second dielectric constant, which may be higher than the first dielectric constant. The second insulating layer 40 may include a metal oxide layer. For example, the second insulating layer 40 may include hafnium oxide and/or aluminum oxide.

Referring to FIG. 9, the gate layer 42 may be formed on the second insulating layer 40, filling the fourth opening 34 and the fifth opening 38. The gate layer 42 may include a metal layer.

Referring back to FIG. 1, the gate layer 42 and second insulating layer 40 may be etched to expose the top surface of the interlayer insulating pattern 30. As a result, the first gate 52 including the gate insulating pattern 42 and the gate electrode 48 may be formed in the first region, and the second gate 54 including the gate insulating pattern 46 and the gate electrode 50 may be formed in the second region.

In exemplary embodiments, the gate insulating pattern 42 of the first gate 52 may be formed by etching the second insulating layer 40. The gate insulating pattern 46 of the second gate 54 may be formed to include the second preliminary insulating pattern 24 and the etched portion of the second insulating layer 40 stacked thereon.

As described above, the first gate 52 may be formed in the first region applied with a low voltage and the second gate 54 may be formed in the second region applied with a high voltage. Here, for a semiconductor device requiring two voltages such as a high voltage and a low voltage, those different voltages may be accommodated by implementing the first gate 52 and the second gate 54 to have different thicknesses.

Hereinafter, a static random access memory (SRAM) device will be described as exemplary embodiments of the inventive concept, but exemplary embodiments of the inventive concept may not be limited thereto.

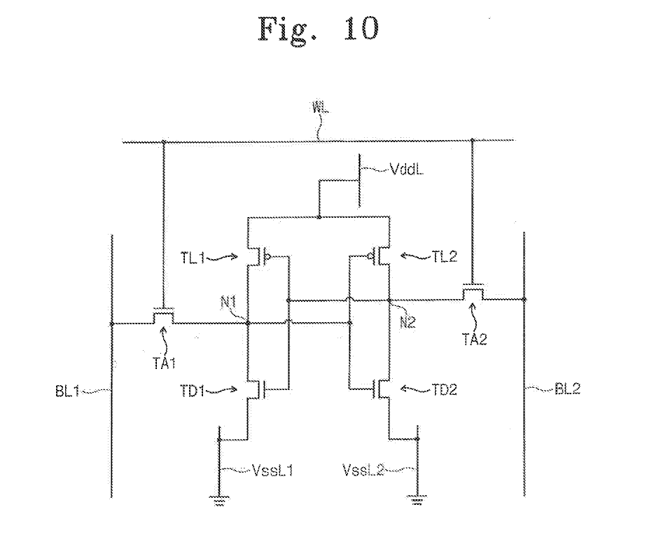

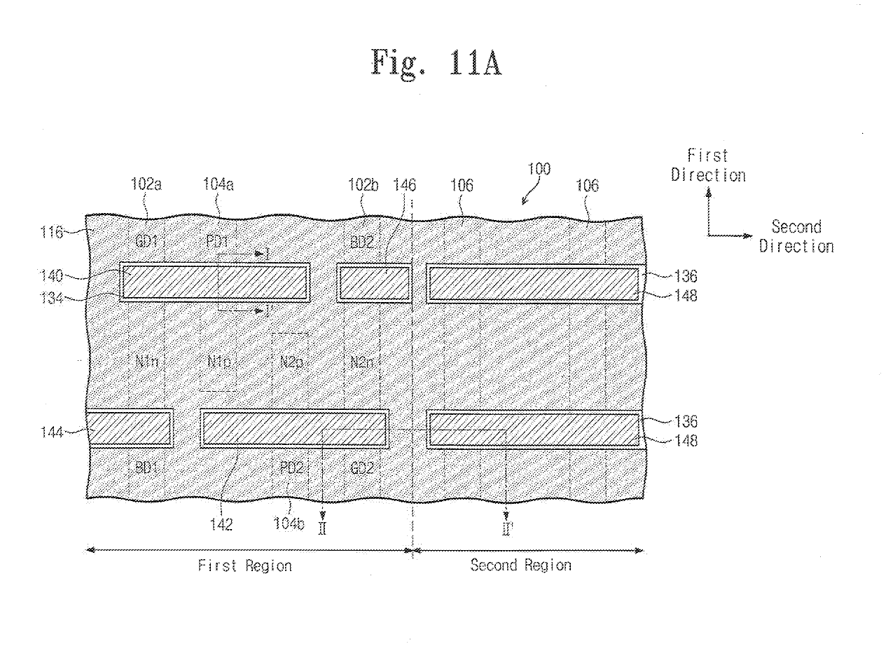

FIG. 10 is a circuit diagram for a static random access memory cell (SRAM cell) according to exemplary embodiments of the inventive concept. Referring to FIG. 10, the SRAM cell may include six transistors: a first load transistor TL1, a first driver transistor TD1, a second load transistor TL2, a second driver transistor TD2, a first access transistor TA1, and a second access transistor TA2. The first and second load transistors TL1 and TL2 may be PMOS transistors. The first and second driver transistors TD1 and TD2 and the first and second access transistors TA1 and TA2 may be NMOS transistors.

A first source/drain of the first load transistor TL1 and a first source/drain of the first driver transistor TD1 may be connected to a first node N1. A second source/drain of the first load transistor TL1 may be connected to a power line VddL, and a second source/drain of the first driver transistor TD1 may be connected to a first ground line VssL1. A gate of the first load transistor TL1 and a gate of the first driver transistor TD1 may be electrically connected to each other. As a result, the first load transistor TL1 and the first driver transistor TD1 may constitute a first inverter. The gates of the first load and driver transistors TL1 and TD1, which are electrically connected to each other, may correspond to an input node of the first inverter, and the first node N1 may correspond to an output node of the first inverter.

A first source/drain of the second load transistor TL2 source/drain and a first source/drain of the second driver transistor TD2 may be connected to a second node N2, and a second source/drain of the second load transistor TL2 may be connected to the power line VddL, and a second source/drain of the second driver transistor TD2 may be connected to a second ground line VssL2. A gate of the second load transistor TL2 and a gate of the second driver transistor TD2 may be electrically connected to each other. As a result, the second load transistor TL2 and the second driver transistor TD2 may constitute a second inverter. The gates of the second load and driver transistors TL2 and TD2, which are electrically connected to each other, may correspond to an input node of the second inverter, and the second node N2 may correspond to an output node of the second inverter.

The first and second inverters may be cross-coupled with each other to constitute a latch structure. For example, the input of the first inverter including the first load and first driver transistors TL1 and TD1 is connected to the second node N2 of the second inverter including the second load and second driver transistors TL2 and TD2. The input of the second inverter is connected to the first node N1 of the first inverter. The first source/drain of the first access transistor TA1 may be connected to the first node N1, and the second source/drain of the first access transistor TA1 may be connected to a first bit line BL1. The first source/drain of the second access transistor TA2 may be connected to the second node N2, and the second source/drain of the second access transistor TA2 may be connected to a second bit line BL2. The gates of the first and second access transistors TA1 and TA2 may be electrically coupled to a word line WL. These connections between the transistors constitute the SRAM cell according to exemplary embodiments of the inventive concepts.

Hereinafter, it will be described a method of fabricating the SRAM cell according to exemplary embodiments of the inventive concept.

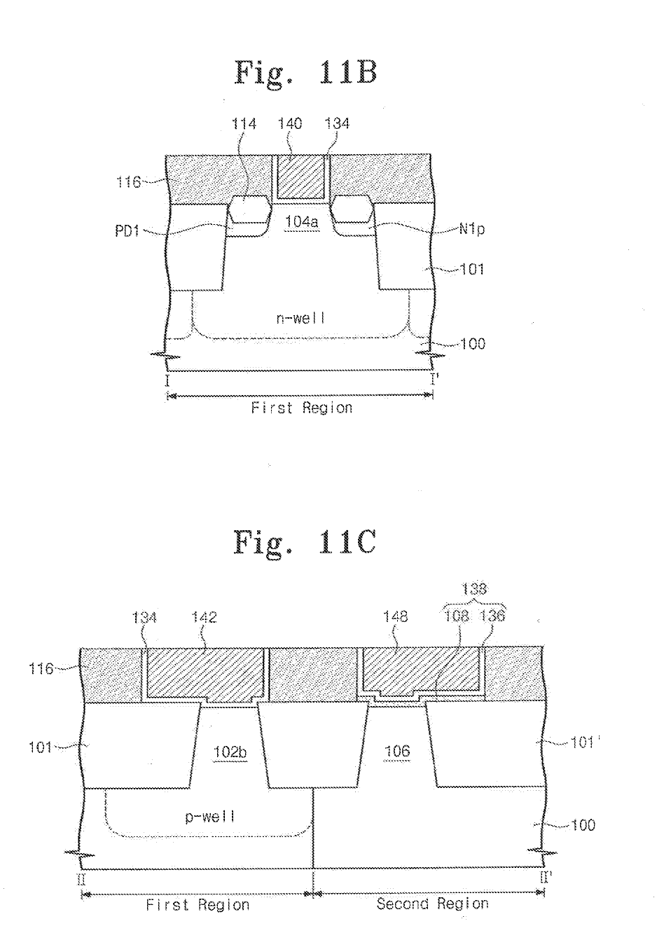

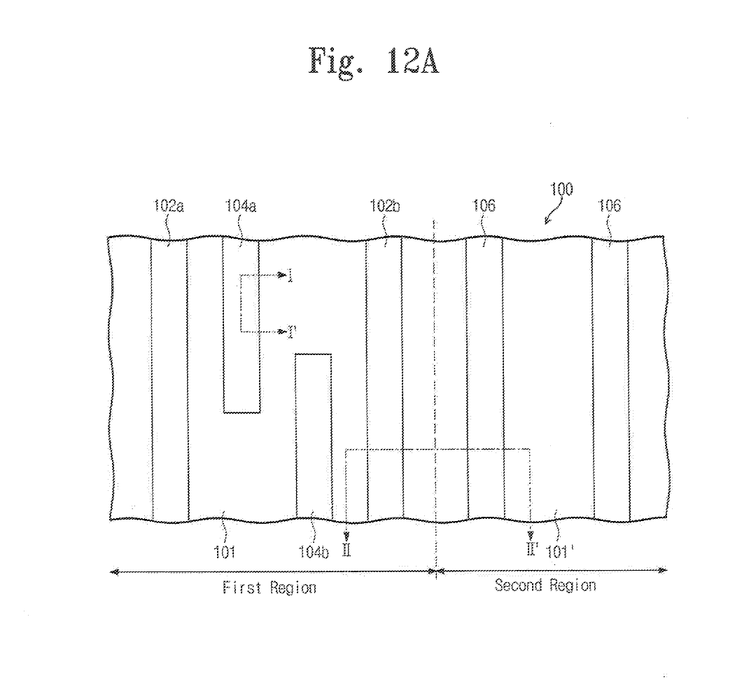

FIG. 11A is a plan view of a semiconductor device according to exemplary embodiments of the inventive concept. FIG. 11B is a sectional view taken along line I-I′ of the semiconductor device of FIG. 11A and FIG. 11C is a sectional view taken along a line II-II′ of the semiconductor device of FIG. 11A.

Referring to FIGS. 11A through 11C, the semiconductor device includes a substrate 100 including a first region and a second region. The semiconductor device further includes first transistors disposed in the first region and second transistors disposed in the second region.

The substrate 100 is a semiconductor substrate. For example, the substrate 100 may be one of a silicon substrate, a germanium substrate, or a silicon-germanium substrate. The first transistors of the first region of the substrate 100 may be applied with a low voltage, and the second transistors of the second region of the substrate 100 may be applied with a high voltage.

The substrate 100 includes active regions 102a, 102b, 104a, 104b, and 106 spaced apart from each other. The active regions 102a, 102b, 104a, 104b, and 106 may be defined by device isolation patterns 101 and 101′ formed in the substrate 100. The active regions 102a, 102b, 104a, 104b, and 106 may be regions of the substrate 100 surrounded by the device isolation patterns 101 and 101′. The active regions 102a, 102b, 104a, 104b, and 106 may include the first active regions 102a, 102b, 104a, and 104b defined by the first device isolation pattern 101 of the first region and the second active region 106 defined by the second device isolation pattern 101′ of the second region.

The first active regions 102a, 102b, 104a, and 104b of the first region, the first device isolation pattern 101, and the first transistors will be described.

The first active regions 102a, 102b, 104a, and 104b may include a first NMOS active region 102a, a second NMOS active region 102b, a first PMOS active region 104a, and a second PMOS active region 104b. The first and second NMOS active regions 102a and 102b may extend along a first direction and be parallel with each other. The first and second PMOS active regions 104a and 104b may be disposed between the first and second NMOS active regions 102a and 102b. The first and second PMOS active regions 104a and 104b may extend along the first direction.

A plurality of SRAM cells may be two-dimensionally arranged in the first region of the substrate 100 along the first and second directions. For example, the SRAM cells are arranged in repetition along the first direction, and the SRAM cells are also arranged in repetition along the second direction. The first NMOS active regions 102a of the SRAM cells arranged along the first direction may be connected to each other and the second NMOS active regions 102b of the SRAM cells arranged along the first direction may be connected to each other. The first PMOS active regions 104a of the SRAM cell may be connected to the first PMOS active region 104a of a first adjacent SRAM cell (not shown here), which is disposed adjacent thereto in the first direction, and the second PMOS active regions 104b of the SRAM cell may be connected to the second PMOS active region 104b of a second adjacent SRAM cell (not shown here), which is disposed adjacent thereto in the first direction. Here, the SRAM cell may be disposed between the first and second adjacent SRAM cells.

The first and second NMOS active regions 102a and 102b may be doped with p-type dopants, and the first and second PMOS active regions 104a and 104b may be doped with n-type dopants. For example, a pair of p-well regions (not shown here) may be formed spaced apart from each other in the substrate 100, and the first and second NMOS active regions 102a and 102b may be defined in the pair of the p-well regions, respectively. The first and second PMOS active regions 104a and 104b may be defined in an n-well region (not shown here) provided in the substrate 100. The n-well region may be disposed between the pair of the p-well regions.

The first transistors disposed in the first region may include first gates 140, 142, 144, and 146, first gate insulating patterns 134 interposed between the first active regions 102a, 102b, 104a, and 104b and the first gates 140, 142, 144, and 146, and first doped regions GD1, N1n, BD1, GD2, N2n, BD2, PD1, N1n, PD2, and N2p.

The first gate 140 may be referred to as a first sharing gate. The first gate 142 may be referred to as a second sharing gate. The first gate 144 may be referred to as a first access gate. The first gate 146 may be referred to as a second access gate 146.

The first sharing gate 140 may extend along the second direction, running across over the first NMOS active region 102a and the first PMOS active regions 104a. An end portion of the first sharing gate 140 disposed on the first device isolation pattern 101 may be adjacent to an end portion of the second PMOS active regions 104b. Here, the end portion of the first sharing gate 140 may be spaced apart from the second PMOS active regions 104b.

The first access gate 144 may extend along the second direction, running across over the first NMOS active region 102a. The first sharing gate 140 and the first access gate 144 may be spaced apart from each other in the first direction.

Similarly, the second sharing gate 142 may extend along the second direction, running across over the second PMOS active region 104b and the second NMOS active region 102b. An end portion of the second sharing gate 142 disposed on the first device isolation pattern 101 may be spaced apart from an end portion of the first PMOS active regions 104a. The second access gate 146 may extend along the second direction, running across over the second NMOS active region 102b. The second sharing gate 142 and the second access gate 146 may be spaced apart from each other in the first direction.

The first access gate 144 of the SRAM cell may be connected to the first access gate 144 of one of neighboring SRAM cells. Similarly, the second access gate 146 of the SRAM cell may be connected to the second access gate 146 of another neighboring the SRAM cell. The first sharing gate 140 and the second access gate 146 may be arranged along the second direction. Similarly, the first access gate 144 and the second sharing gate 142 may be arranged along the second direction. Accordingly, as described with reference to FIG. 11A, the first sharing gate 140 and the second sharing gate 142 may be disposed to be symmetric with respect to a center point of the SRAM cell, and the first access gate 144 and the second access gate 146 may be also disposed to be symmetric with respect to the center point of the SRAM cell.

The first gate insulating patterns 134 may be interposed between the first gates 140, 142, 144, and 146 and the first active regions 102a, 102b, 104a, and 104b. According to an embodiment of the inventive concept, each of the first gate insulating patterns 134 may be disposed on the first active regions 102a, 102b, 104a, and 104b and also be disposed on the side surfaces of the first gates 140, 142, 144, and 146. According to some aspects of the inventive concept, the first gate insulating patterns 134 may be formed of metal oxide, such as hafnium oxide or aluminum oxide.

The first doped regions GD1, N1n, BD1, GD2, N2n, BD2, PD1, N1p, PD2, and N2p may include a first n-type node doped region N1n, a first ground doped region GD1, a first bit doped region BD1, a first p-type node doped region N1p, a first power doped region PD1, a second n-type node doped region N2n, a second ground doped region GD2, a second bit doped region BD2, a second p-type node doped region N2p, and a second power doped region PD2.

The first n-type node doped region N1n may be disposed in the first NMOS active region 102a between the first sharing gate 140 and the first access gate 144. The first ground doped region GD1 may be provided in the first NMOS active region 102a disposed at the other side of the first sharing gate 140. The first sharing gate 140 may be disposed over the first NMOS active region 102a between the first ground doped region GD1 and the first n-type node doped region N1n. The first bit doped region BD1 may be provided in the first NMOS active region 102a disposed at the other side of the first access gate 144. The first access gate 144 may be disposed on the first NMOS active region 102a between the first bit doped region BD1 and the first n-type node doped region N1n. The first p-type node doped region N1p and the first power doped region PD1 may be spaced apart from each other in the first PMOS active regions 104a, and the first sharing gate 140 may be disposed on the first PMOS active regions 104a between the first p-type node doped region N1p and the first power doped region PD1. The first ground doped region GD1 and the first power doped region PD1 may be aligned along the second direction. The first n-type node doped region N1n and the first p-type node doped region N1p may be aligned along the second direction.

Similarly, the second n-type node doped region N2n may be disposed in the second NMOS active region 102b between the second sharing gate 142 and the second access gate 146, and the second ground doped region GD2 may be provided in the second NMOS active region 102b disposed at the other side of the second sharing gate 142. The second sharing gate 142 may be disposed over the first NMOS active region 102a between the second ground doped region GD2 and the second n-type node doped region N2n. The second bit doped region BD2 may be provided in the second NMOS active region 102b disposed at the other side of the second access gate 146, and the second access gate 146 may be disposed on the second NMOS active region 102b between the second bit doped region BD2 and the second n-type node doped region N2n. The second p-type node doped region N2p and the second power doped region PD2 may be disposed spaced apart from each other in the second PMOS active regions 104b, and the second sharing gate 142 may be disposed on the second PMOS active regions 104b between the second p-type node doped region N2p and the second power doped region PD2.

The second ground doped region GD2, the second power doped region PD2 and the first bit doped region BD1 may be aligned along the second direction. The first ground doped region GD1, the first power doped region PD1 and the second bit doped region BD2 may be aligned along the second direction. The first n-type node doped region N1n, the first p-type node doped region N1p, the second p-type node doped region N2p and second n-type node doped region N2n may be aligned along the second direction. The first and second ground doped regions GD1 and GD2 may be disposed to be symmetric with respect to the center point of the SRAM cell, and the first and second bit doped regions BD1 and BD2 may be disposed to be symmetric with respect to the center point of the SRAM cell. The first doped regions GD1, N1n, BD1, GD2, N2n, and BD2 formed in the first and second NMOS active regions 102a and 102b may be doped with n-type dopants, and the doped regions PD1, N1p, PD2, and N2p formed in the first and second PMOS active regions 104a, 104b may be doped with p-type dopants.

According to exemplary embodiments of the inventive concept, patterns 114 may be disposed in the doped regions PD1, N1p, PD2, and N2p to create a compressive stress on channel regions of the active regions 104a and 104b. Each of patterns 114 may have the compressive residual stress by including silicon germanium (SiGe). The compressive stress applied to the channel regions increases mobility of holes passing through the channels of PMOS transistors. That is, electric characteristics of PMOS transistor can be improved by the patterns 114, which are provided in the first and second PMOS active regions 104a and 104b to have the compressive residual stress.

Referring to FIGS. 10 and 11A through 11C, the first driver transistor TD1 of FIG. 10 is disposed on the first NMOS active region 102a. The first driver transistor TD1 includes the first sharing gate 140, the first n-type node doped region N1n, and the first ground doped region GD1. The first n-type node doped region N1n may serve as the first source/drain of the first driver transistor TD1, and the first ground doped region GD1 may serve as the second source/drain of the first driver transistor TD1. The first access transistor TA1 of FIG. 10 may include the first access gate 144, the first n-type node doped region N1n, and the first bit doped region BD1. The first n-type node doped region N1n may serve as the first source/drain of the first access transistor TA1. In other words, the first n-type node doped region N1n may serve as the first source/drain of the first driver transistor TD1 and as the first source/drain of the first access transistor TA1. The first driver and first access transistors TD1 and TA1 may share the first n-type node doped region N1n.

The first load transistor TL1 of FIG. 10 is disposed on the first PMOS active region 104a. The first load transistor TL1 includes the first sharing gate 140, the first power doped region PD1, and the first p-type node doped region N1p. The first p-type node doped region N1p may serve as the first source/drain of the first load transistor TL1, and the first power doped region PD1 may serve as the second source/drain of the first load transistor TL1.

Similarly, the second driver transistor TD2 of FIG. 10 is disposed on the second NMOS active region 102b. The second driver transistor TD2 includes the second sharing gate 142, the second n-type node doped region N2n, and the second ground doped region GD2. The second n-type node doped region N2n may serve as the first source/drain of the second driver transistor TD2, and the second ground doped region GD2 may serve as the second source/drain of the second driver transistor TD2.

The second access transistor TA2 of FIG. 10 is disposed on the second NMOS active region 102b. The second access transistor includes the second access gate 146, the second n-type node doped region N2n, and the second bit doped region BD2. The second n-type node doped region N2n may serve as the first source/drain of the second access transistor TA2. In other words, the second driver and access transistors TD2 and TA2 may share the second n-type node doped region N2n.

The second load transistor TL2 of FIG. 10 is disposed on the second PMOS active region 104b. The second load transistor TL2 includes the second sharing gate 142, the second power doped region PD2, and the second p-type node doped region N2p. The second p-type node doped region N2p may serve as the first source/drain of the second load transistor TL2, and the second power doped region PD2 may serve as the second source/drain of the second load transistor TL2.

Hereinafter, the second active region 106, the second device isolation pattern 101′, and the second transistor of the second region will be described below. The second region includes transistors for logic circuits requiring a higher voltage than required for the SRAM cell. Such logic circuits may include a functional block such as an I/O device. The second active region 106 is defined by the second device isolation pattern 101′. The second active region 106 may be a NMOS active region. Alternatively, the second active region 106 may be a PMOS active region. The second region may include a plurality of the second active regions 106. In exemplary embodiments, the plurality of the second active regions 106 may extend along the first direction and be parallel with each other. Alternatively, the plurality of the second active regions 106 may extend along the second direction and be parallel with each other. Exemplary embodiments of the inventive concept will not be limited to a specific type of the second active region 106.

The second transistor may include a second gate 148, a second gate insulating pattern 138 interposed between the second gate 148 and the substrate 100, and a second doped regions (not shown). The second transistor may be an NMOS or PMOS transistor. Exemplary embodiment of the inventive concept will not be limited to a specific type of the second transistor.

Referring to FIG. 11A, the second active region 106 extends along the first direction, and the second gates 148 may extend along the second direction, running across over the second active region 106. The second region may include a plurality of the second gates 148 spaced apart from each other in the first direction.

The second gate 148 may be formed of a metal or a metal compound. For example, the second gate 148 may include at least one selected from the group of titanium, tantalum, tungsten, tantalum, titanium nitride, or titanium aluminum.

According to an exemplary embodiment of the inventive concept, the second gate insulating pattern 138 may include a first gate insulating pattern 108 disposed on the second active region 106 and a second gate insulating pattern 136 surrounding the bottom and the side surfaces of the second gate 148. The first gate insulating pattern 108 may include a material having a first dielectric constant and, for example, be formed to contain silicon oxide, silicon nitride and/or silicon oxynitride. The second gate insulating pattern 136 may include a material having a second dielectric constant greater than that of the first dielectric constant, and for example, be formed to contain a metal oxide layer (e.g., hafnium oxide or aluminum oxide). The first gate insulating patterns 134 and the second gate insulating pattern 136 may contain substantially the same material as each other. As described above, the second gate insulating pattern 138 of the second transistor may be configured to have stacked insulating patterns of the first and second gate insulating patterns 108 and 136, and thus, it is possible to apply a high voltage to the second gate 148.

The second doped region (not shown here) may be formed in the second active region 106, which is disposed adjacent to both sides of the second gate 148, to serve as a source/drain of the second transistor.

According to an embodiment of the inventive concept, the top surfaces of the first gates 140, 142, 144, and 146 may be substantially coplanar to the top surface of the second gate 148. A height of the second gate insulating pattern 138 may be greater than that of each of the first gate insulating patterns 134.

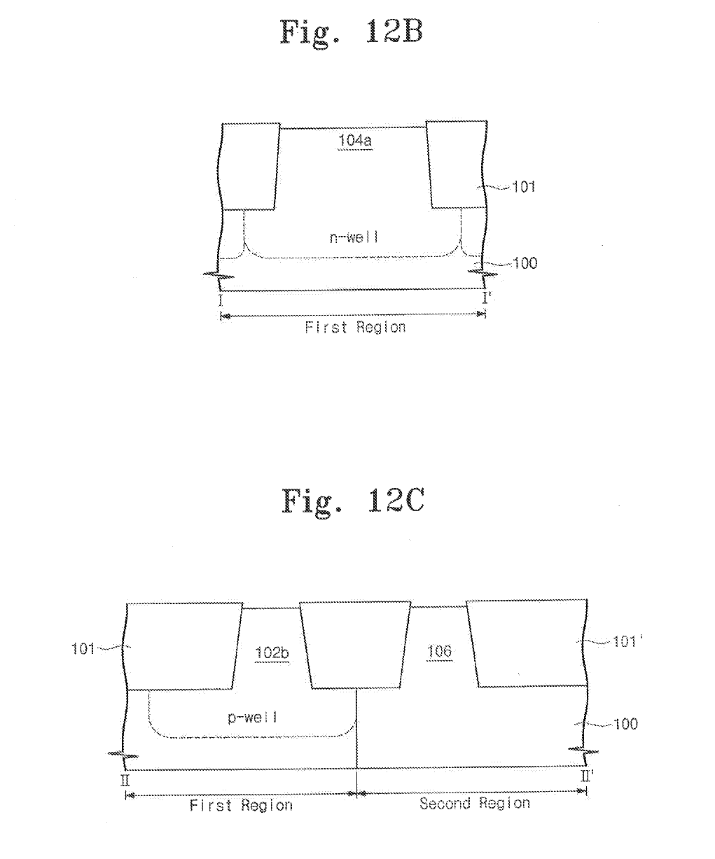

FIGS. 12A through 17A are plan views illustrating a method of fabricating a semiconductor device according to exemplary embodiments of the inventive concept. FIGS. 12B through 17B are sectional views taken along lines I-I′ of FIGS. 12A through 17A, respectively, and FIGS. 12C through 17C are sectional views taken along lines II-II′ of FIGS. 12A through 17A, respectively.

Referring to FIGS. 12A, 12B, and 12C, well regions may be formed in the substrate 100, and the device isolation patterns 101 and 101′ may be formed to define active regions 102a, 102b, 104a, 104b, and 106.

The substrate 100 may be a semiconductor substrate, which may be, for example, formed of a silicon substrate, a germanium substrate, or a silicon-germanium substrate. The substrate 100 may include the first region and the second region.

The SRAM cells may be disposed in the first region of the substrate 100. The first region includes p-well regions and n-well regions. The second region includes transistors for logic circuits requiring a higher voltage than required for the SRAM cell. Such logic circuits may include an I/O device. P-well regions may be formed in the second region. However, exemplary embodiments of the inventive concept will not be limited to a specific type of the well region of the second region.

The device isolation pattern 101 and 101′ may be formed in the substrate 100 using a shallow-trench isolation (STI) process. The device isolation patterns 101 and 101′ may include the first device isolation pattern 101 provided in the first region and the second device isolation pattern 101′ provided in the second region. First active regions 102a, 102b, 104a, and 104b of the first region may be defined by the first device isolation pattern 101, and a second active region 106 of the second region may be defined by the second device isolation pattern 101′.

According to exemplary embodiments of the inventive concept, the first active regions 102a, 102b, 104a, and 104b may include the first NMOS active region 102a, the second NMOS active region 102b, the first PMOS active region 104a, and the second PMOS active region 104b. The first and second NMOS active regions 102a and 102b may extend in parallel with each other in the first direction. The first and second PMOS active regions 104a and 104b may extend in parallel with each other in the first direction. The first and second PMOS active regions 104a and 104b may be disposed between the first and second NMOS active regions 102a and 102b. Furthermore, the second active region 106 may extend along the first direction.

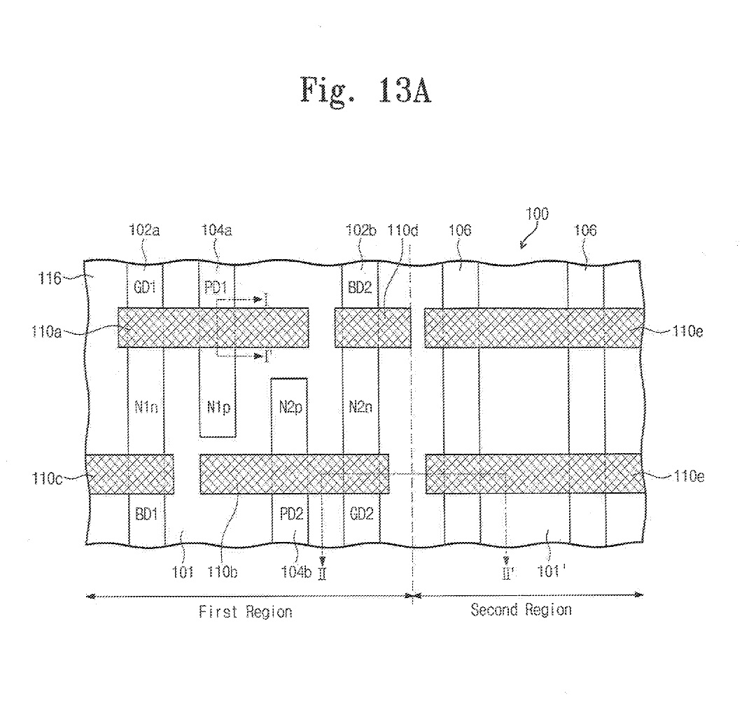

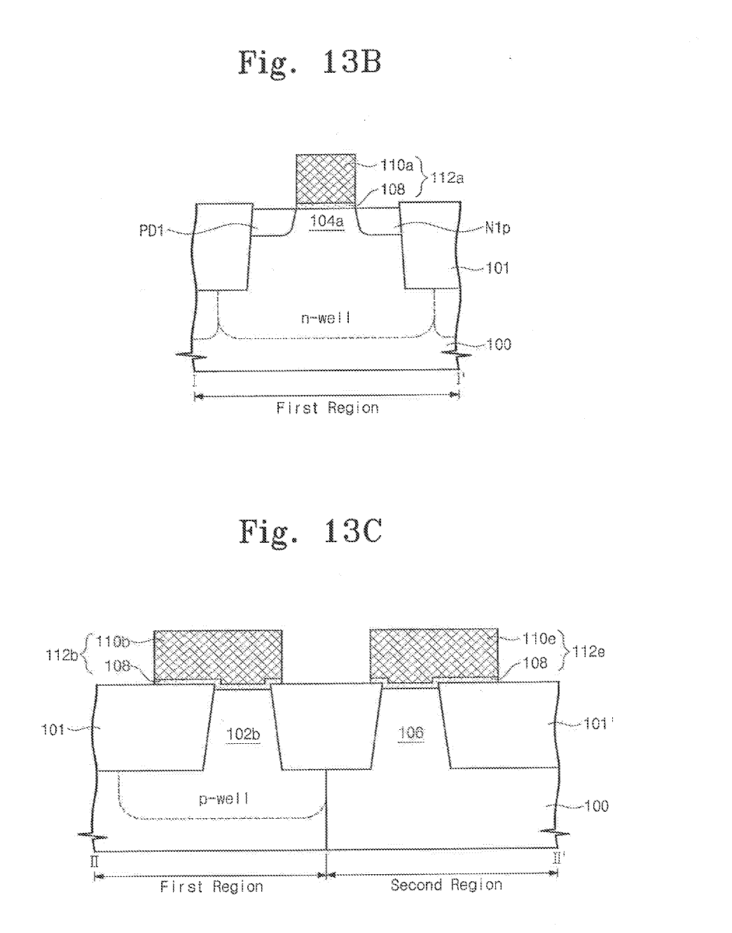

Referring to FIGS. 13A, 13B, and 13C, first gate insulating patterns 108 and sacrificial patterns 110a, 110b, 110c, 110d, and 110e may be formed on the substrate 100. In addition, doped regions GD1, N1n, BD1, GD2, N2n, BD2, PD1, N1p, PD2, and N2p may be formed in the substrate 100.

For example, a first gate insulating layer (not shown) and a sacrificial layer (not shown) may be formed on the substrate 100. The first gate insulating layer may be formed of a material having a first dielectric constant and be, for example, formed of silicon oxide, silicon nitride and/or silicon oxynitride. The sacrificial layer may be formed of polysilicon. The sacrificial layer and the first gate insulating layer may be etched to form patterned structure. For example, as shown in FIGS. 13B and 13C, the patterned structures 112a, 112b, and 112e includes the first gate insulating patterns 108 and the sacrificial patterns 110a, 110b, and 110e.

In the first region, the first sacrificial pattern 110a may be configured to run across over the first NMOS active region 102a and the first PMOS active region 104a in the second direction. The second sacrificial pattern 110b may be configured to run across over the second NMOS active region 102b and the second PMOS active region 104b in the second direction. The third sacrificial pattern 110c may be configured to cross over the first NMOS active region 102a in the second direction, and the fourth sacrificial pattern 110d may be configured to cross over the second NMOS active region 102b in the second direction. In the second region, the fifth sacrificial pattern 110e may run across over the second active region 106.

The first gate insulating patterns 108 may be formed between the active regions 102a, 102b, 104a, 104b, and 106 and the first to fifth sacrificial patterns 110a, 110b, 110c, 110d, and 110e.

Thereafter, the doped regions GD1, N1n, BD1, GD2, N2n, BD2, PD1, Nip, PD2, and N2p may be formed in the active regions 102a, 102b, 104a, 104b, and 106 using the patterned structures 110a, 110b, 110c, 110d, and 110e as ion injection masks. The doped regions GD1, N1n, BD1, GD2, N2n, and BD2 may be formed in the NMOS active regions 102a and 102b and the doped regions PD1, N1p, PD2, and N2p may be formed in the PMOS active regions 104a and 104b.

In exemplary embodiments, the doped regions GD1, N1n, BD1, GD2, N2n, and BD2 may be formed in the NMOS active regions 102a and 102b, and then, the doped regions PD1, N1p, PD2, and N2p may be formed in the PMOS active regions 104a and 104b. In other embodiments, the doped regions PD1, N1p, PD2, and N2p may be formed in the PMOS active regions 104a and 104b, and then, the doped regions GD1, N1n, BD1, GD2, N2n, and BD2 may be formed in the NMOS active regions 102a and 102b.

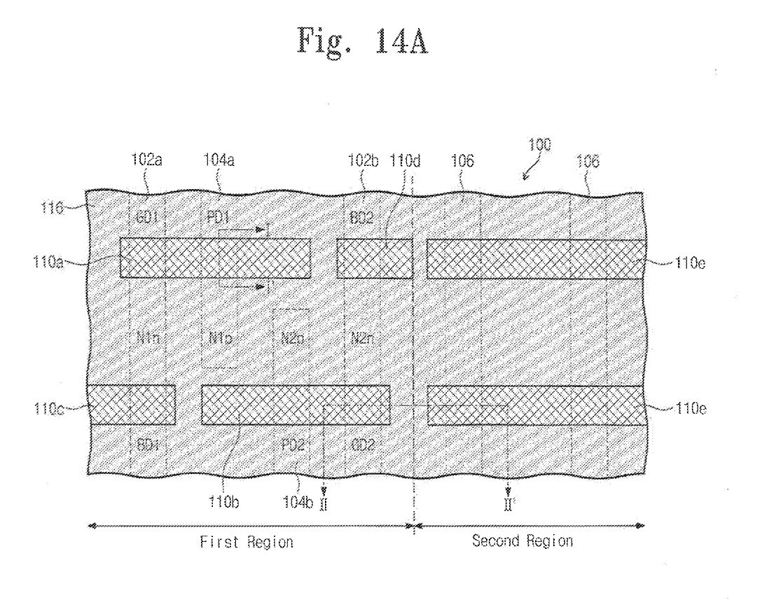

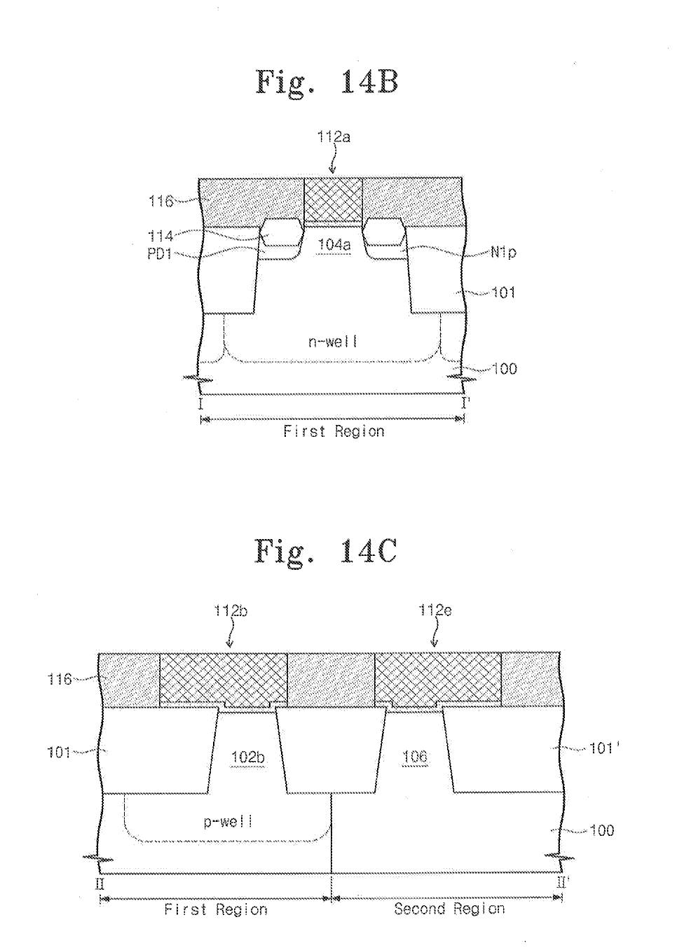

Referring to FIGS. 14A, 14B, and 14C, interlayer insulating patterns 116 may be formed to fill spaces between the patterned structures 110a, 110b, 110c, 110d, and 110e.

An interlayered insulating layer (not shown) may be formed on the substrate 100 provided with the patterned structures 110a, 110b, 110c, 110d, and 110e to fill gap regions between the patterned structures 110a, 110b, 110c, 110d, and 110e. The interlayered insulating layer may include a material having an etch selectivity with respect to the patterned structures 110a, 110b, 110 c, 110d, and 110e. For example, the interlayered insulating layer may include oxide, nitride or oxynitride. The interlayered insulating layer may be etched to the level of the top surfaces of the patterned structures 110a, 110b, 110c, 110d, and 110e to form the interlayer insulating patterns 116 between the patterned structures 110a, 110b, 110c, 110d, and 110e.

According to other embodiments of the inventive concept, the patterns 114 having a compressive stress may be further formed in the structures 112c and 112d formed in the PMOS active regions 104a and 104b.

The formation of the patterns 114 having the compressive stress may include forming a layer (not shown here) having the compressive stress on the patterned structure 112a. The layer is patterned to form the patterns 114. A thermal treatment is performed on the structure 112a. However, exemplary embodiments of the inventive concept will not be limited to the example in which the patterns 114 are formed to have the compressive stress property.

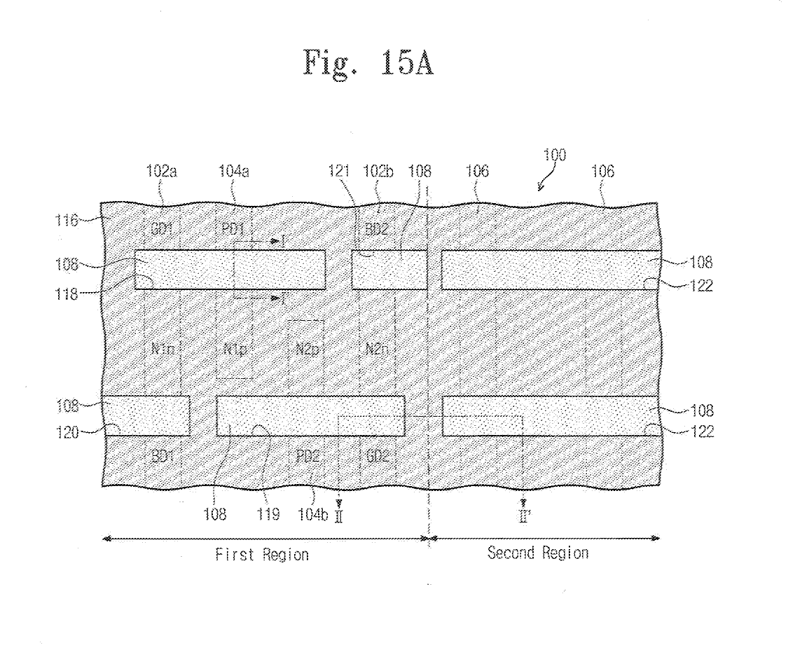

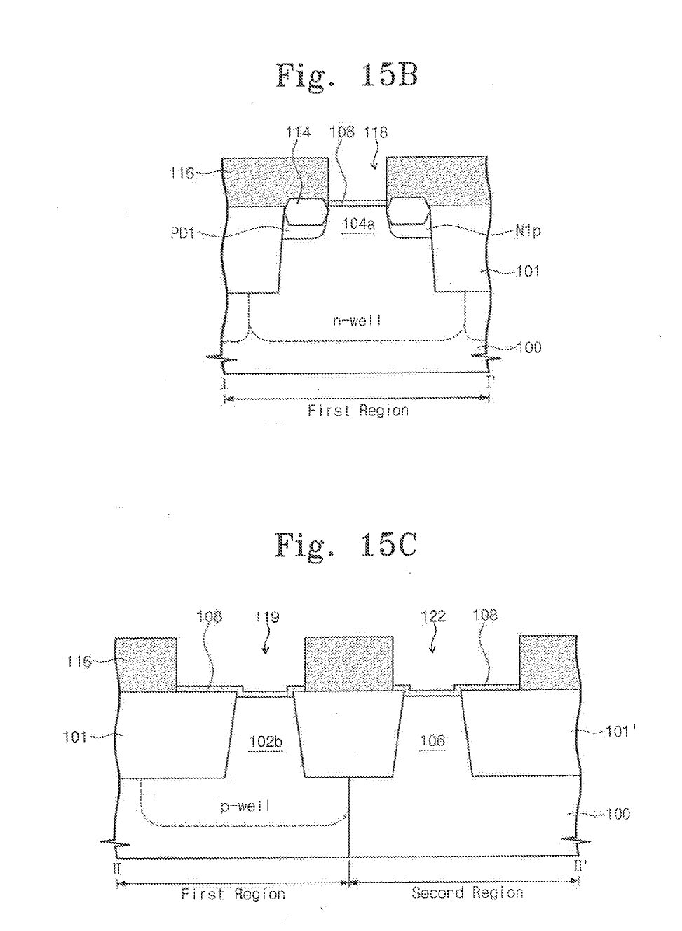

Referring to FIGS. 15A, 15B, and 15C, the sacrificial patterns 110a, 110b, 110c, 110d, and 110e may be removed to form openings 118, 119, 120, 121, and 122. For example, as shown in FIGS. 15B and 15C, the openings include a first opening 118, a second opening 119, and a fifth opening 122 exposing the first gate insulating patterns 108.

For example, the sacrificial patterns 110a, 110b, 110c, 110d, and 110e are formed of polysilicon and the interlayer insulating patterns 116 are formed of silicon oxide. The sacrificial patterns 110a, 110b, 110c, 110d, and 110e may be removed using an etchant that etches polysilicon selectively. Due to the removal of the first to fifth sacrificial patterns 110a, 110b, 110c, 110d, and 110e, the first to fifth openings 118, 119, 120, 121, and 122 may be defined by the interlayer insulating patterns 116 and expose the first gate insulating patterns 108. For example, the first to fourth openings 118, 119, 120, and 121 may be formed in the first region, and the fifth opening 122 may be formed in the second region.

In exemplary embodiments, the first to fifth openings 118, 119, 120, 121, and 122 may be used as molds in the subsequent process of forming the gates 140, 142, 144, 146, and 148, as shown in FIGS. 11A, 11B, and 11C.

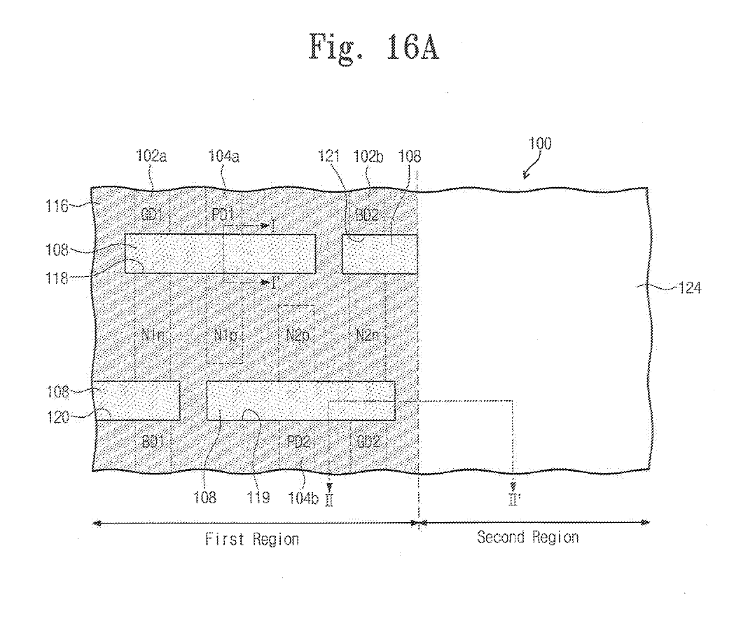

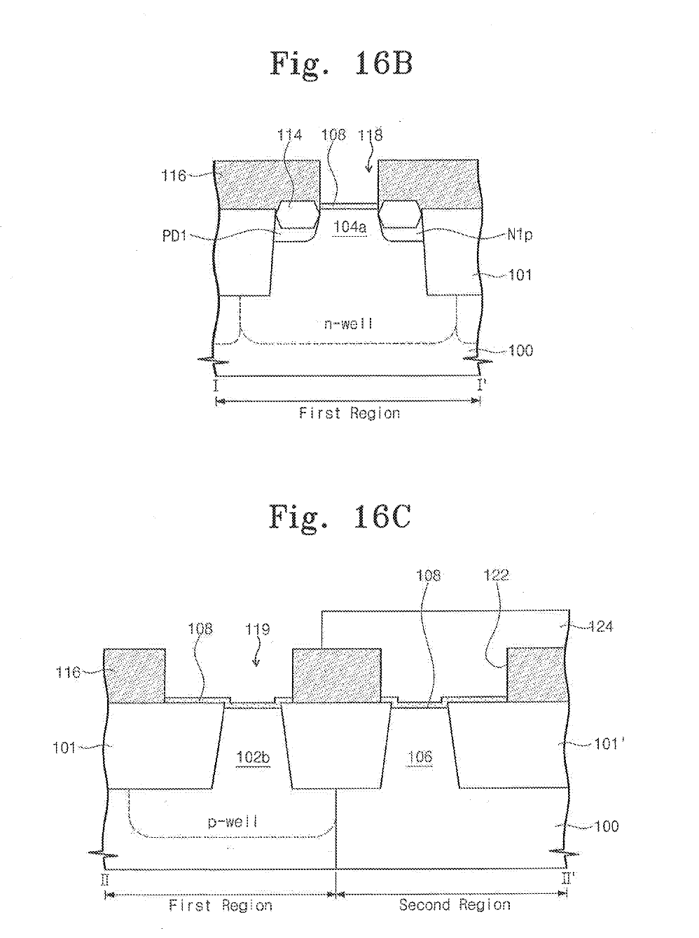

Referring to FIGS. 16A, 16B, and 16C, a mask 124 is formed to protect the first gate insulating pattern 108 of the second region.

In exemplary embodiments, the mask 124 is formed to cover the second region and to fill completely the fifth opening 122. The mask 124 may be formed of a photoresist layer.

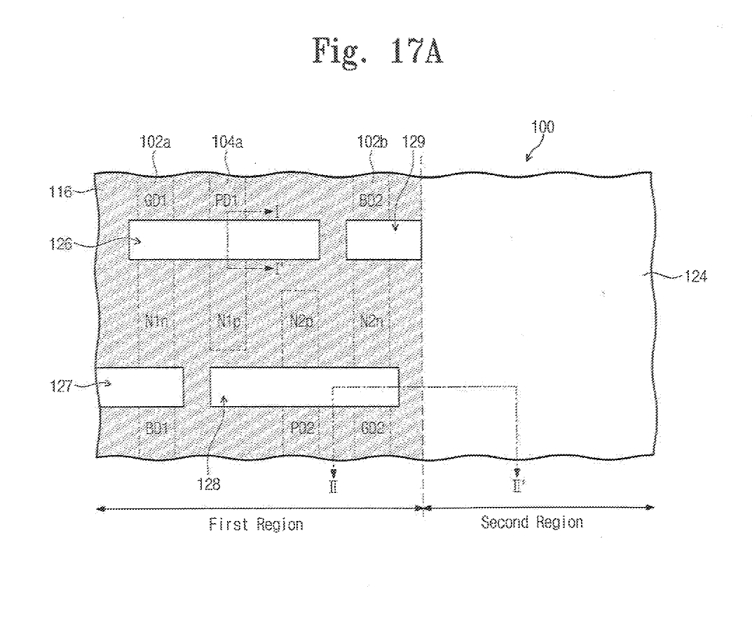

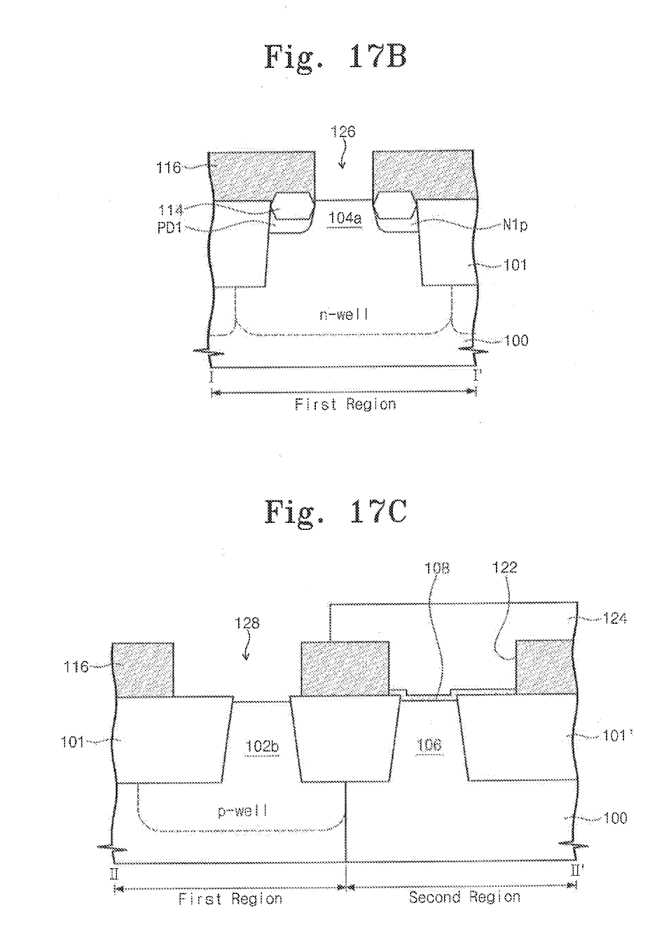

Referring to FIGS. 17A, 17B, and 17C, the exposed first gate insulating patterns 108 are removed to form sixth to ninth openings 126, 127, 128, and 129.

After the removal of the first gate insulating patterns 108 of the first region, the mask 124 may be removed to expose the first gate insulating pattern 108 of the fifth opening in the second region.

Referring back to FIGS. 10, 11A, 11B, and 11C, the first gate insulating patterns 134, the first gates 140, 142, 144, and 146, the second gate insulating pattern 138, and the second gate 148 may be formed by filling fill the fifth to ninth openings 122, 126, 127, 128, and 129.

For example, a second gate insulating layer (not shown) may be conformally formed on the interlayer insulating patterns 116 having the fifth to ninth openings 122, 126, 127, 128, and 129. The second gate insulating layer may be formed to a thickness that the second gate insulating layer does not fill completely the fifth to ninth openings 122, 126, 127, 128, and 129. The second gate insulating layer may include a material having a second dielectric constant greater than the first dielectric constant. The second gate insulating layer may include a metal oxide, such as hafnium oxide or aluminum oxide. The second gate insulating layer may be formed using an atomic layer deposition or a chemical vapor deposition.

A conductive layer (not shown here) may be formed to a thickness enough to fill completely the fifth to ninth openings 122, 126, 127, 128, and 129 provided with the second gate insulating layer. The conductive layer may include metal or metal compound. For example, the conductive layer may include at least one selected from the group of titanium, tantalum, tungsten, aluminum, titanium nitride, or titanium aluminum. The conductive layer and the second gate insulating layer may be etched to expose the top surfaces of the interlayer insulating patterns 116, thereby forming the conductive patterns 140, 142, 144, 146, and 148, the first gate insulating patterns 134 and the second gate insulating patterns 136. The conductive patterns of the first region may serve as the first gates 140, 142, 144, and 146, and the conductive pattern of the second region may serve as the second gate 148. The second gate insulating layer patterned in the first region may serve as the first gate insulating patterns 134 and the second gate insulating layer patterned in the second region may serve as the second gate insulating pattern 138. Each of the second gate insulating patterns 136 may be formed to have a vertical section shaped like a letter “U”.

In exemplary embodiments of the inventive concept, the first gate insulating patterns 134 and the first gates 140, 142, 144, and 146 may be formed in the first region. According to some aspects of the inventive concept, the first gate insulating patterns 134 may be formed to have a structure surrounding the bottom and the side surfaces of the first gates 140, 142, 144, and 146, respectively. As shown in FIGS. 11B and 11C, each of the first gate insulating patterns 134 may be formed to have a vertical section shaped like a letter “U”.

The sixth opening 126 may be filled with the first common gate 140, the seventh opening 127 may be filled with the second common gate 144, the eighth opening 128 may be filled with the first access gate 142, and the ninth opening 129 may be filled with the second access gate 146.

The second gate insulating pattern 138 and the second gate 148 of FIG. 11C may be formed in the second region. In exemplary embodiments, the second gate insulating pattern 138 may include the first gate insulating pattern 108 and the second gate insulating pattern 136. As shown in FIGS. 11B and 11C, the first gate insulating pattern 108 of the second gate insulating pattern 138 may be disposed on the second active region 106, and the second gate insulating pattern 136 may be disposed on the first gate insulating pattern 108 to have a vertical section shaped like a letter “U”. The second gate 148 may fill the fifth opening 122.

The first gates 140, 142, 144, and 146 and the second gate 148 may be formed by a damascene process in the openings 122, 126, 127, 128, and 129 respectively. Accordingly, the first gate insulating patterns 134 may be formed to have a different thickness from the second gate insulating pattern 138, and the first gates 140, 142, 144, and 146 may be formed to have substantially the same height as the second gate 148. As a result, a wire-forming process may be subsequently performed on the planarized surface.

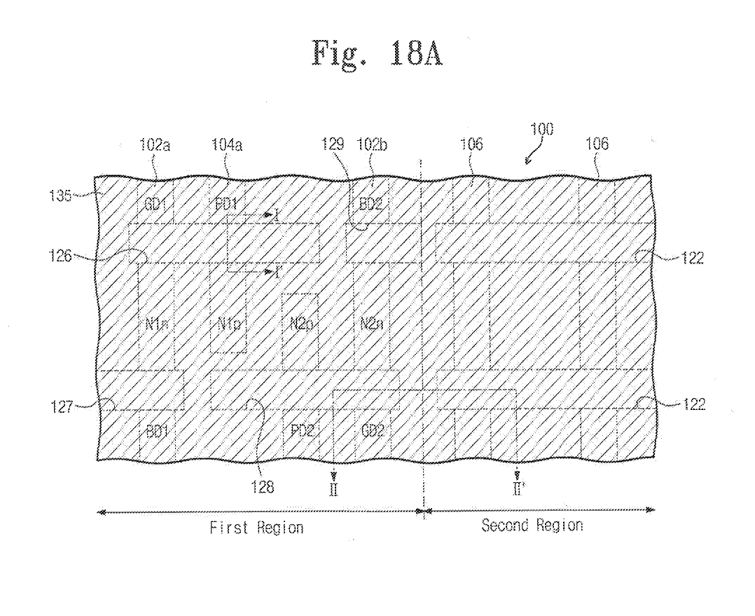

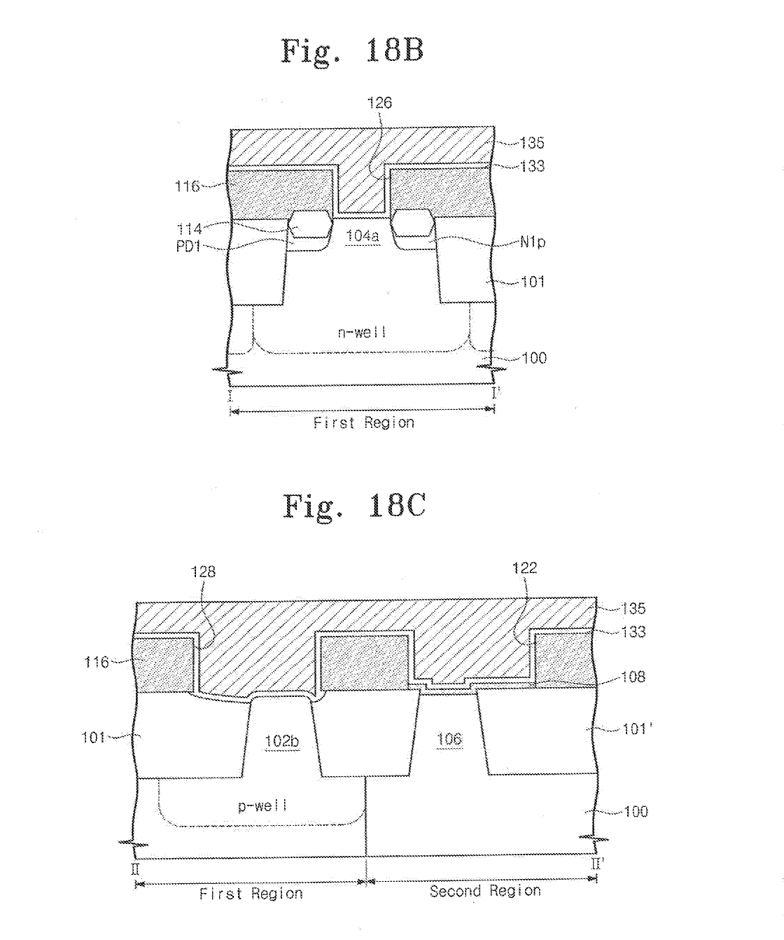

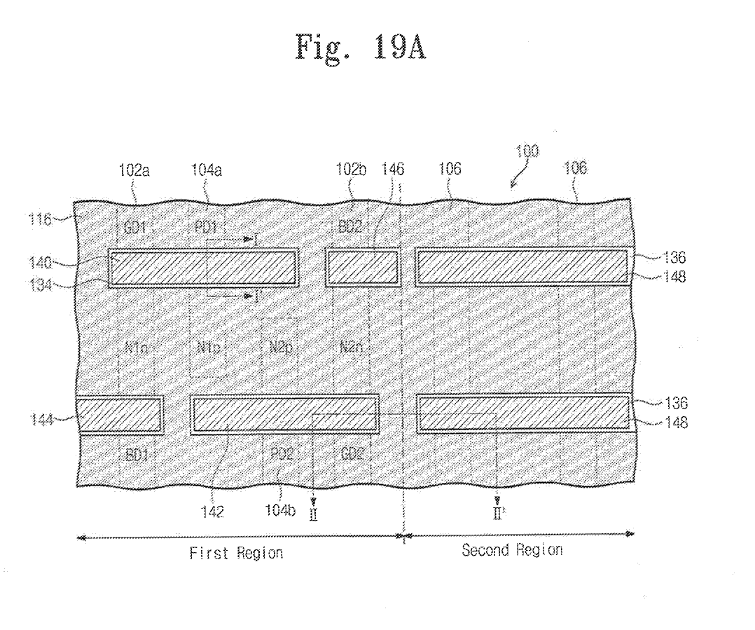

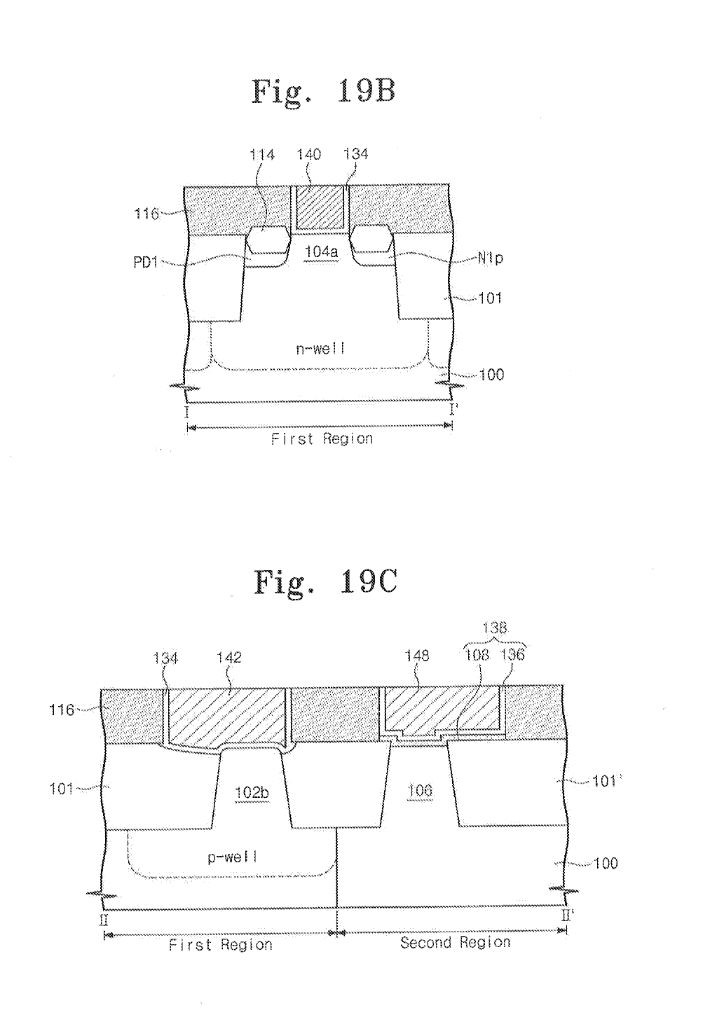

FIGS. 18A and 19A are plan views illustrating a method of fabricating a semiconductor device according to exemplary embodiments of the inventive concept. FIGS. 18B and 19B are sectional views taken along lines I-I′ of FIGS. 18A and 19A, respectively, and FIGS. 18C and 19C are sectional views taken along lines II-II′ of FIGS. 18A and 19A, respectively.

The process steps shown in FIGS. 12A through 16C are carried out in the same way in this embodiment. Detailed descriptions about such process steps will be omitted here.

Referring to FIGS. 18A through 18C, the first gate insulating patterns 108 exposed by the first to fourth openings 118, 119, 120, and 121 may be removed to form the sixth to ninth openings 126, 127, 128, and 129.

The first gate insulating patterns 108 may include a layer of oxide, and the first device isolation pattern 101 may include a layer of oxide. The first gate insulating patterns 108 are overetched such that the top surfaces of the first device isolation pattern 101 and the first active region 102b are further etched down. Due to their different etching rates, the top surface of the first device isolation pattern 101 is etched down further than that of the first active region 12.

Accordingly, the first active region 102b includes the upper portion protruded from its adjacent first device isolation pattern 101. The protruded upper portion of the first active region 102b includes round corners.

After the removal of the first gate insulating patterns 108 of the first region, the mask 124 may be removed from the second region.

According to some aspects of the inventive concept, the round corners of the first active regions 102a, 102b, 104a, and 104b increases their channel width.

Referring to FIGS. 19A, 19B, and 19C, the second gate insulating pattern 138 and the second gate 148 are formed in the fifth opening 122. The first gate insulating patterns 134 and the first gates 140, 142, 144, and 146 are formed in the sixth to ninth openings 126, 127, 128, and 129.

For example, a second gate insulating layer 133 is conformally formed on the first active regions 102a, 102b, 104a, and 104b exposed by the sixth to ninth openings 126, 127, 128, and 129. The second gate insulating layer is also formed on the first gate insulating pattern 108 and the interlayer insulating patterns 116 exposed by the fifth opening 122. A conductive layer 135 is formed on the second gate insulating layer 133 to fill the fifth to ninth openings 122, 126, 127, 128, and 129. The conductive layer may include metal or metal compound. For example, the conductive layer may include at least one selected from the group consisting of titanium, tantalum, tungsten, aluminum, titanium nitride, titanium aluminum.

The conductive layer 135 and the second gate insulating layer 133 may be etched to the level of the top surfaces of the interlayer insulating patterns so that the conductive patterns 140, 142, 144, 146, and 148 and the second gate insulating patterns 136 are formed. The conductive patterns may serve as the first gates 140, 142, 144, and 146 and the second gate 148, and the second gate insulating patterns 136 may serve as the first gate insulating patterns 134 and the second gate insulating pattern 138. Each of the second gate insulating patterns 136 may have a vertical section shaped like a letter “U”.

In exemplary embodiments of the inventive concept, the first gate insulating patterns 134 and the first gates 140, 142, 144, and 146 may be formed on the first region. According to some aspects of the inventive concept, the first gate insulating patterns 134 may be formed to have a structure surrounding bottom and side surfaces of the first gates 140, 142, 144, and 146, respectively. As shown in FIGS. 19B and 19C, each of the first gate insulating patterns 134 may be formed to have a vertical section shaped like a letter “U”.

The sixth opening 126 may be filled with the first common gate 140, the seventh opening 127 may be filled with the second common gate 144, the eighth opening 128 may be filled with the first access gate 142, and the ninth opening 129 may be filled with the second access gate 146.

The second gate insulating pattern 138 and the second gate 148 may be formed in the second region. In exemplary embodiments, the second gate insulating pattern 138 includes the first gate insulating pattern 108 and the second gate insulating pattern 136. As shown in FIGS. 19B and 19C, the first gate insulating pattern 108 of the second gate insulating pattern 138 is disposed on the second active region 106, and the second gate insulating pattern 136 may be disposed on the first gate insulating pattern 108 to have a vertical section shaped like a letter “U”. The second gate 148 may fill the fifth opening 122.

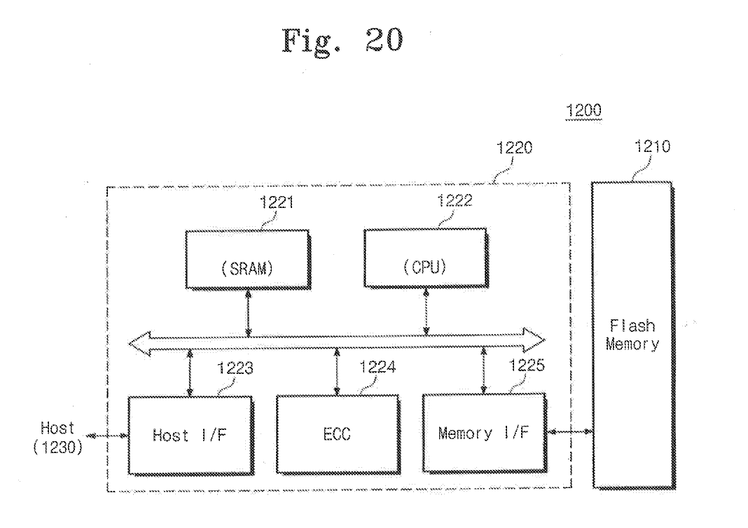

FIG. 20 is a block diagram of a memory card including a semiconductor device with a SRAM cell according to exemplary embodiments of the inventive concept.

Referring to FIG. 20, a memory card 1200 may include a FLASH memory 1210 to support a high data storage capacity. The memory card 1200 may include a memory controller 1220 that controls data exchange between a host 1230 and the FLASH memory 1210. An SRAM 1221 may be used as a working memory of a central processing unit (CPU) 1222 and be one of those described in the previous exemplary embodiments of the inventive concept.

A host interface 1223 may have the data exchange protocol of the host 1230 connected to the memory card 1200. An error correction code (ECC) 1224 may detect/correct an error in data read from the FLASH memory 1210. A memory interface 1225 may interface with the FLASH memory 1210. The CPU 1222 may perform an overall control operation to exchange data to and/or from the memory controller 1220. Although not illustrated in FIG. 11, the memory card 1200 may further include a read-only memory (ROM) storing code data to interface with the host 1230.

According to exemplary embodiments of the inventive concept, it is possible to realize easily a semiconductor device including transistors, which may be applied with voltages different from each other and be provided on a single substrate. In addition, due to the active region protruding from the device isolation pattern, it is possible to increase substantially an effective length of a channel region and consequently to improve electric reliability of the transistors.

While exemplary embodiments of the inventive concepts have been particularly shown and described, it will be understood by one of ordinary skill in the art that variations in form and detail may be made therein without departing from the spirit and scope of the attached claims.

1. A semiconductor device, comprising:
a first device isolation pattern defining a first active region;
a second device isolation pattern defining a second active region;
a first gate disposed on the first active region, the first gate including a gate insulating pattern of a first thickness; and
a second gate disposed on the second active region, the second gate including a gate insulating pattern of a second thickness greater than the first thickness,
wherein a top surface of the first device isolation pattern is curved down toward the first active region such that the first active region has an upper portion protruded from the top surface and rounded corners, and
wherein a first voltage level is applied to the first gate, and a second voltage level is applied to the second gate, the second voltage level being higher than the first voltage level.

2. The device of claim 1, wherein the gate insulating pattern of the second gate includes a silicon oxide layer disposed on the second active region and a metal oxide layer disposed on the silicon oxide layer.

3. The device of claim 2, wherein the gate insulating pattern of the first gate is the metal oxide layer.

4. (canceled)

5. The device claim 1, wherein the rounded corners increase an effective width of the first gate.

6. The device claim 5, wherein the second gate is PMOS transistor and includes patterns in source/drain regions, the patterns having compressive residual stress.

7. A semiconductor device comprising:
a static random access memory cell (SRAM cell) transistor including a gate insulating pattern of a first thickness and an active region having rounded corners, wherein the rounded corners increase an effective width of the static memory cell transistor; and
a transistor including a gate insulating pattern of a second thickness greater than the first thickness,
wherein a first voltage level is applied to the static memory cell transistor and a second voltage level higher than the first voltage level is applied to the transistor.

8. The device of claim 7, wherein the gate insulating pattern of the transistor includes a silicon oxide layer disposed on the second active region and a metal oxide layer disposed on the silicon oxide layer.

9. The device of claim 8, wherein the gate insulating pattern of the SRAM cell transistor is the metal oxide layer.

10. The device of claim 9, wherein the transistor is a PMOS transistor including source/drain regions, the source/drain regions including patterns having compressive residual stress.
